(19) United States
(12) Patent Application Publication
(10) Pub. No.: US 2012/0098584 A1
(43) Pub. Date: Apr. 26, 2012

(54) CIRCUIT AND METHOD FOR IMPROVEMENT OF A LEVEL SHIFTER

(75) Inventors: HUNG-AN HUANG, MIAOLI COUNTY (TW); YUNG-YUAN LIU, MIAOLI COUNTY (TW)

(73) Assignee: FITIPOWER INTEGRATED TECHNOLOGY INC., MIAOLI COUNTY (TW)

(21) Appl. No.: 13/271,270

(22) Filed: Oct. 12, 2011

(30) Foreign Application Priority Data
Oct. 20, 2010 (TW) 099135696

(51) Int. Cl. H03L 5/00

(52) U.S. Cl. 327/333

(57) ABSTRACT

A current limiter is connected between a voltage source and the level shifting latch of a level shifter for limiting the driving current for the level shifting latch under a threshold, to thereby reduce the current consumption of the level shifter during logic transition, by which the level shifting latch can be implemented by transistors with shorter channels, thereby downsizing the circuit area of the level shifter. Preferably, the threshold is adjustable for adjusting the output driving capability of the level shifter and speeding up logic transition of the level shifter.

### FIELD OF THE INVENTION

The present invention is related generally to a level shifter and, more particularly, to a circuit and method for improvement of the output driving capability of a level shifter.

### BACKGROUND OF THE INVENTION

Generally, a circuit may use multiple power supplies providing various potentials for the circuit, and for communications between signals based on the power supplies providing different potentials, the signals will be adjusted to a same potential by a level shifter for normal operation of the circuit. For example, referring to FIG. 1, in a conventional low-to-high level shifter, transistors M1 and M2 are used to amplify low-voltage complementary input signals In1 and In2, typically representative of logic 1 with the highest potential of a low-voltage source VDD and logic 0 with the same potential as of a voltage source VSS, respectively. Since the signals In1 and In2 are complementary to each other, when the signal In1 is logic 1, the signal In2 is logic 0, and on the contrary, when the signal In1 is logic 0, the signal In2 is logic 1. Transistors M3 and M4 have their gates and drains cross-coupled to establish a level shifting latch and have their sources connected with a high-voltage source VHH, for shifting the logic 1 from the VDD system to the VHH system. The complementary input signals In1 and In2 of the VDD system will generate complementary output signals Out1 and Out2 of the VHH system, having the same logic states as the input signals Inl and In2 respectively. For example, in the event that the signal In1 is logic 1 and the signal In2 is logic 0, the signal Out1 will be logic 1 of and the signal Out2 will be logic 0 (with the potential VSS).

Assuming that the input signals In1 and In2 are logic 1 and logic 0 respectively, the output signals Out1 and Out2 will be latched at logic 1 and logic 0 respectively. In this state, the transistors M1 and M4 are on, and the transistors M2 and M3 are off. When the input signals In1 and In2 turn to logic 0 and logic 1 respectively, the transistor M2 will turn on and the transistor M1 will turn off. Before into steady state, however, the output signals Out1 and Out2 still stay at the original states (of logic 1 and logic 0 respectively) at beginning, not changing to logic 0 and logic 1 yet, and thus the transistor M4 is still on and the transistor M3 is still off. In this transient state, since the transistors M2 and M4 are on at the same time, there will be a leakage current flowing from the high-voltage source VHH through the transistors M2 and M4 to the low-voltage source VSS, and thereby causing power loss. Furthermore, after logic transition of the input signals In1 and In2, when the output signal Out1 is going to turn to logic 0 from logic 1, since the transistors M2 and M4 are both on, a seesaw action happens because the transistor M2 is to pull the output signal Out1 low toward the potential VSS, and the transistor M4 is to pull the output signal Out1 high toward the potential VHH. For smooth logic transition of the output signal Out1, conventionally, the transistor M4 is provided with a longer channel for the transistor M4 to be inferior to the transistor M2 in current driving capability. However, doing so always leads to larger circuit area of an integrated circuit and thereby higher manufacturing costs for the resultant IC.

### SUMMARY OF THE INVENTION

An objective of the present invention is to reduce the current consumption of a level shifter during logic transition.

Another objective of the present invention is to downsize the circuit area of a level shifter.

Yet another objective of the present invention is to provide a level shifter having adjustable output driving capability.

A further objective of the present invention is to provide a level shifter having faster logic transition.

According to the present invention, a current limiter is connected between the level shifting latch of a level shifter and a voltage source powering the level shifter, for limiting the driving current of the level shifting latch under a threshold, to thereby reduce the current consumption during logic transition of the level shifter. In addition, the level shifting latch can be implemented by transistors of shorter channels, thereby downsizing the circuit of the level shifter.

The threshold is preferably adjustable, by which the level shifter will have adjustable output driving capability and faster logic transition speed.

### BRIEF DESCRIPTION OF THE DRAWINGS

These and other objectives, features and advantages of the present invention will become apparent to those skilled in the art upon consideration of the following description of the preferred embodiments of the present invention taken in conjunction with the accompanying drawings, in which:

FIG. 1 is a conventional low-to-high level shifter;

FIG. 2 is a first embodiment according to the present invention;

FIG. 3 shows the voltage levels of the logic states of the level shifter shown in FIG. 2;

FIG. 4 is a second embodiment according to the present invention; and

FIG. 5 shows the voltage levels of the logic states of the level shifter shown in FIG. 4.

### DETAILED DESCRIPTION OF THE INVENTION

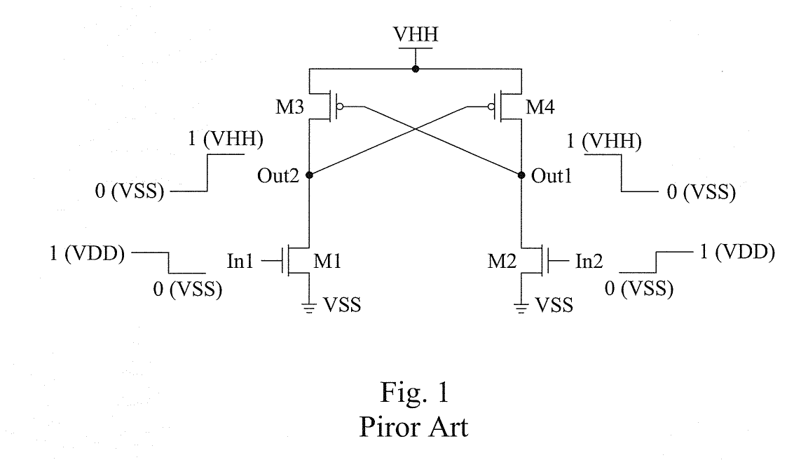

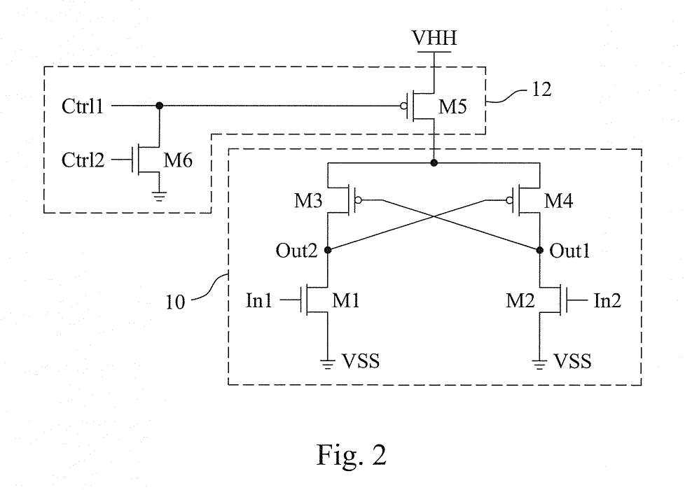

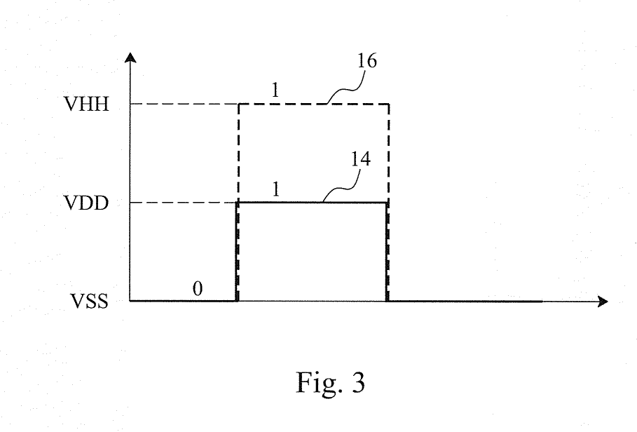

As shown in FIG. 2, based on the low-to-high level shifter 10 shown in FIG. 1, a current limiter 12 is connected between the level shifting latch and the high-voltage source VHH of the level shifter 10. The current limiter 12 includes a transistor M5 connected between the level shifting latch and the high-voltage source VHH, and has its current controlled by a control signal Ctrl1. When the control signal Ctrl1 has a lower voltage, the transistor M5 may provide a larger current for the level shifting latch of the level shifter 10. On the contrary, when the control signal Ctrl1 has a higher voltage, the transistor M5 will provide a smaller current. When this improved level shifter is in normal operation, the control signal Ctrl1 has a certain voltage to set the maximum current that the transistor M5 would generate. The certain voltage for the control signal Ctrl1 may be provided by any reference voltage source. Assuming that the input signals In1 and In2 are presently logic 1 and logic 0 respectively, the output signals Out1 and Out2 will be latched at logic 1 and logic 0 of the VHH system. The voltage levels corresponding to the logic states of the VDD system and the VHH system are shown in FIG. 3, in which waveform 14 indicates the voltage levels of the input signals In1 and In2, and waveform 16 indicates the voltage levels of the output signals Out1 and Out2. When the input signals In1 and In2 turn to logic 0 and logic 1 respectively, the transistors M2 and M4 will be both on at beginning, thereby establishing is a leakage current path from the high-voltage source VHH to the low-voltage source VSS through the transistors M5, M4 and M2. However, due to the transistor M5 present in the leakage current path to limit the leakage current under the maximum current that the transistor M5 would generate, the power consumption of the level shifter during the logic transition is reduced. In addition, during the seesaw action between the transistors M2 and M4, due to the current limiting effect provided by the transistor M5, the current available for the transistor M4 to pull the output signal Out1 high is under the limiting current, so that the pulling capability of the transistor M4 is much less than the conventional circuit. Therefore, the output signals Out1 and Out2 can have smooth logic transition without the need of longer channel transistor M4. Consequently, the level shifter can be implemented by smaller circuit area of an integrated circuit.

Preferably, the limiting current provided by the transistor M5 is adjustable to adjust the output driving capability of the level shifter. For instance, as shown in FIG. 2, the current limiter 12 further includes a transistor M6 connected between the gate Ctrl1 of the transistor M5 and the voltage source VSS, and controlled by a control signal Ctrl2 to adjust the limiting current provided by the transistor M5. When the level shifter has a lighter load, the control signal Ctrl2 is fixed at logic 0 to keep the transistor M6 off, and the current of the transistor M5 is controlled by the voltage level of the control signal Ctrl1. In the case of a heavy load, the control signal Ctrl2 is set at logic 1, of either high-voltage source or low-voltage source, for the transistor M6 to be in a conductive state, which will pull the gate voltage Ctrl1 of the transistor M5 low to logic 0, thereby making the transistor M5 fully on, with the benefit of increasing the driving current and in turn speeding up the logic transition of the level shifter.

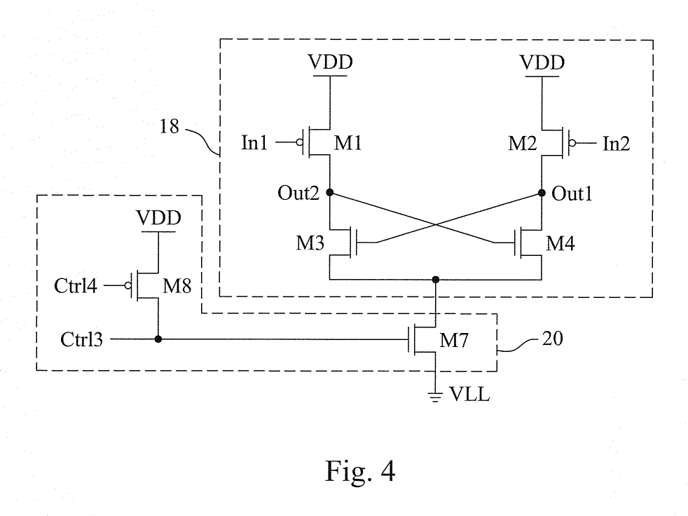

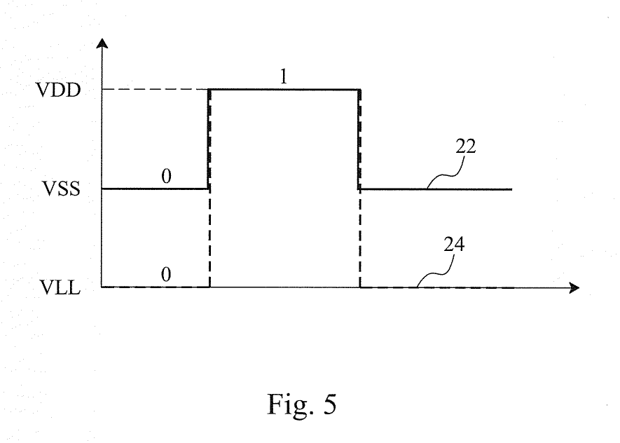

FIG. 4 is a second embodiment according to the present invention, which is designed based on a conventional level shifter 18 for level shifting of logic 0 of input signals In1 and In2 for potential VSS to a lower potential VLL. Referring to FIG. 5, waveform 22 indicates the voltage levels of the input signals In1 and In2, and waveform 24 indicates the voltage levels of the output signals Out1 and Out2. In this improved level shifter, a current limiter 20 is inserter between the level shifting latch of the level shifter 18 and the voltage source VLL. The current limiter 20 includes a transistor M7 that is controlled by a control signal Ctrl3 and functions the same as the transistor M5 depicted in FIG. 2. Additionally, the current limiter 20 further includes a transistor M8 connected between the gate Ctrl3 of the transistor M7 and the voltage source VDD, controlled by a control signal Ctr4 and functioning the same as the transistor M6 depicted in FIG. 2.

While the present invention has been described in conjunction with preferred embodiments thereof, it is evident that many alternatives, modifications and variations will be apparent to those skilled in the art. Accordingly, it is intended to embrace all such alternatives, modifications and variations that fall within the spirit and scope thereof as set forth in the appended claims.

What is claimed is:

1. A level shifter comprising:
a level shifting latch to be connected with a voltage source; and
a current limiter connected between the voltage source and the level shifting latch for limiting a driving current for the level shifting latch under a threshold.

2. The level shifter of claim 1, wherein the threshold is adjustable.

3. The level shifter of claim 1, wherein the current limiter comprises a transistor connected between the voltage source and the level shifting latch, having a control terminal receiving a control signal for determining the threshold.

4. The level shifter of claim 3, wherein the current limiter further comprises a second transistor connected between the control terminal and a second voltage source, having a control terminal receiving a second control signal to adjust the threshold.

5. The level shifter of claim 4, wherein the second control signal adjusts the threshold depending on a loading of the level shifter.

6. The level shifter of claim 5, wherein the threshold is larger when the loading is heavier.

7. A method for improvement of a level shifter having a level shifting latch to be connected with a voltage source, the method comprising the steps of:
connecting a current limiter between the voltage source and the level shifting latch; and
limiting a driving current for the level shifting latch under a threshold by controlling the current limiter.

8. The method of claim 7, further comprising the step of adjusting the threshold.

9. The method of claim 7, further comprising the step of applying a control signal to control a transistor connected between the voltage source and the level shifting latch for determining the threshold.

10. The method of claim 9, further comprising the step of adjusting the control signal to adjust the threshold.

11. The method of claim 10, further comprising the step of adjusting the threshold depending on a loading of the level shifter.

12. The method of claim 11, wherein the threshold is larger when the loading is heavier.
